(19) United States
(12) Patent Application Publication
(10) Pub. No.: US 2017/0244027 A1
(43) Pub. Date: Aug. 24, 2017

(54) METHOD PROVIDING FOR A STORAGE ELEMENT

(71) Applicant: ARM Ltd., Cambridge (GB)

(72) Inventors: Kimberly Gay Reid, Austin, TX (US); Lucian Shifren, San Jose, CA (US)

(21) Appl. No.: 15/048,778

(22) Filed: Feb. 19, 2016

(51) Int. Cl. H01L 45/00

(52) U.S. Cl. CPC H01L 45/08; H01L 45/146; H01L 45/147; H01L 45/1616; H01L 45/1226

(57) ABSTRACT

A method for forming a thin film comprising a metal, metal compound, or metal oxide on a substrate, which method comprises forming one or more thin film layers of a metal or metal oxide by a deposition process employing reactant precursors and/or relative amounts thereof which are selected to deposit a thin film layer with a controlled amount of dopant derived from at least one reactant precursor.

### CROSS REFERENCE TO RELATED APPLICATIONS

This application is related to U.S. patent application Ser. No. 15/048,244, titled “FABRICATION OF CORRELATED ELECTRON MATERIAL DEVICES METHOD TO CONTROL CARBON,” filed on Feb. 19, 2016, and incorporated herein by reference in its entirety.

The present disclosure is concerned with a method for forming a thin film comprising a metal or metal compound (such as a metal oxide or nitride) wherein one or more thin film layers are formed with a controlled amount of dopant. The film may be used in a correlated electron device.

The method may, in particular, comprise forming a plurality of thin film layers with a controlled amount of dopant wherein the controlled amount of dopant in one thin film layer is different to that in another thin film layer.

Such a method has particular application to the manufacture of a storage element, such as a memory element, based on a correlated electron material (CEM) providing a correlated electron switch (CES).

The present disclosure, therefore, is also concerned with a storage element comprising a correlated electron switch as well as with a method for its manufacture.

A correlated electron switch (CES) is a particular type of switch formed (wholly or in part) from a correlated electron material (CEM). Such a switch may be used both as non-volatile storage as well as part of control circuitry to sense a state of a target correlated electron switch.

A correlated electron switch exhibits an abrupt conductive or insulative state transition arising from electron correlations rather than solid state structural phase changes (examples of solid state structural phases include crystalline-amorphous in phase change memory devices or filamentary formation and conduction in resistive random access memory devices. An abrupt conductor-insulator transition in a correlated electron switch may be responsive to a quantum mechanical phenomenon in contrast to melting-solidification or filament formation.

A quantum mechanical transition of a correlated electron switch may be understood in terms of a Mott transition. In a Mott transition, the material may switch from an insulative state to a conductive state if a Mott transition condition occurs. When a critical carrier concentration is achieved such that a Mott criteria is met, the Mott transition will occur and the state will change from high resistance (or capacitance) to low resistance (or capacitance).

A “state” or “memory state” of a device comprising a correlated electron switch element (CES element) may be dependent on the impedance state or conductive state of the element. In this context, the state or memory state means a detectable state of the element which is indicative of a value, symbol, parameter or condition (for example).

In one particular implementation, described below, a memory state may be detected, at least in part, on the basis a signal detected on the terminals of the CES element in a read operation. In another particular implementation, also described below, the CES element may be placed in a particular memory state to represent or store a particular value, symbol or parameter by application of one or more signals across the terminals of the device in a “write operation”.

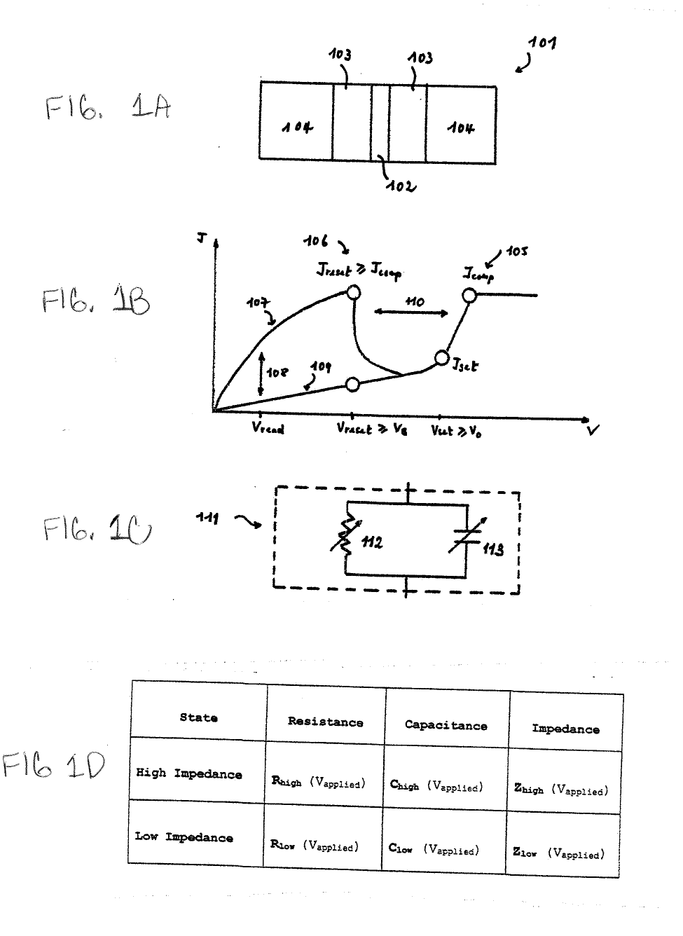

In one implementation, shown in FIG. 1 A, the CES element may comprise a correlated electron material sandwiched between conductive terminals. By applying a specific voltage and current between the terminals, the material may transition between the aforementioned conductive and insulative states. As discussed in the particular implementations below, the material may be placed in an insulative state by application of a first programming signal across the terminals having a voltage Vreset and current Iᵣₑₛₑₜ at a current density Jᵣₑₛₑₜ, or placed in a conductive state by application of a second programming signal across the terminals having a voltage Vₛₑₜ and current Iₛₑₜ at current density Jₛₑₜ.

Additionally or alternatively, the CES element may be provided as a memory cell in a cross-point memory array whereby the element may comprise a metal/CEM/metal stack formed on a semiconductor. Such a stack may be formed on a diode, for example. The diode may, for example, be a junction diode or a Schottky diode. In this context, it should be understood that “metal” means a conductor, viz., any material that acts like a metal including, for example, polysilicon or a doped semiconductor.

FIG. 1 A shows one implementation of a storage element comprising a correlated electron switch. The CES element 101 and 103, which may function as a correlated electron random access memory (CeRAM), comprises an arrangement in which a switching region 102 (S) is provided between two conductive regions made of CEM 103 (C). The conductive regions may comprise or be provided with respective terminal electrodes 104 for the storage element.

The conductive regions 103 may comprise any material which is conducting relative to region 102 at the operating voltages applied to the element. Suitable materials for the conductive regions include transition metals, transition metal compounds and transition metal.

The switching region 102 comprises a correlated electron material which is capable of switching from a conductor state to an insulator state (and vice-a-versa) at an operating voltage applied to the element. Suitable correlated electron materials for the switching region include transition metals, transition metal compounds, and transition metals oxides which are capable of acting as a Mott insulator, a charge exchange insulator or an Anderson disorder insulator under the operating conditions of the element.

FIG. 1 B shows a plot of current density (J) voltage applied across the terminals of the CES element. Based, at least in part, on a voltage applied to the terminals (e.g. in a write operation), the CES element may be placed in a conductive state or an insulative state.

For example, application of a voltage Vₛₑₜ and current density Jₛₑₜ may place the element in a conductive memory state and application of a voltage Vᵣₑₛₑₜ and a current density Jᵣₑₛₑₜ may place the element in an insulative memory state.

Following placement of the CES element in an insulative state or conductive state, the particular state of the element may be detected by the application of a voltage Vread (e.g. in a read operation) and detection of, for example, a current or current density at the terminals or a bias across the terminals of the element.

Both the current and the voltage of the element need to be controlled in order to switch the element state. For example, if the element is in a conductive state, and voltage Vᵣₑₛₑₜ required to place the device in an insulative memory state, is applied, the element will not switch to the insulative state until the current density is at the required value of Jᵣₑₛₑₜ. This means that, when the element is used to read/write from a memory, unintended rewrites may be prevented.

When sufficient bias is applied (e.g. exceeding a band-splitting potential) and the aforementioned Mott condition is met (injected holes=electrons in a switching region), the CES element may rapidly switch from a conductive state to an insulative state via the Mott transition. This may occur as shown by 108 of the plot. At this point, electrons are no longer screened from each other and become localised. This correlation may result in a strong electron-electron interaction potential which splits the bands to from an insulator.

While the element is still in the insulative state, current may be generated by transportation of electron holes. When sufficient bias is applied across the terminals of the element, electrons may be injected into a metal-insulator-metal (MIM) diode over the potential barrier of the MIM device. When sufficient electrons have been injected and sufficient potential is applied across the terminals to place the element in a set state, an increase in electrons may reinstate screening and remove the localisation of the electrons, which may collapse the band-splitting potential and thereby form a metal.

Current in the CES element may be controlled by an externally applied “compliance” condition determined, at least in part, on the basis of an external current limited during a write operation to place the element in a conductive state. This externally applied compliance current may also set a condition of a current density for a subsequent reset operation to place the element in an insulative state.

As shown in FIG. 1 B, a current density J_{comp} applied during a write operation at point 105 to place the element in a conductive state may determine a compliance condition for placing the element in an insulative in a subsequent write operation. For example, the element may be subsequently placed in an insulative state by application of a current density Jᵣₑₛₑₜ≧J_{comp} at a voltage Vᵣₑₛₑₜ shown at point 106, where J_{comp} is externally applied.

The compliance condition may, therefore, set a number of electrons in the element which are to be “captured” by holes for the Mott transition. In other words, a current applied in a write operation to place the element in a conductive memory state may determine a number of holes to be injected to the element for subsequently transitioning the element to an insulative memory state.

As pointed out above, a reset condition may occur in response to a Mott transition at point 106. Such a Mott transition may occur at a condition in the element in which a concentration of electrons n equals a concentration of electron holes p.

A current or current density in a region 107 of the plot shown in FIG. 1 may exist in response to injection of holes from a voltage signal applied across the terminals of the element. Here, injection of holes may meet a Mott transition criterion for the conductive state to insulative state transition as a critical voltage applied across the terminals of the element.

A “read window” 108 for detecting a memory state of the element in a read operation may be set out as a difference between a portion 109 of the plot shown in FIG. 1 while the element is in an insulative state and a portion 107 while the element is in a conductive state at a read voltage V_{read}.

Similarly, a “write window” 110 for placing the CES element in an insulative or conductive memory state in a write operation may be set out as a difference between Vᵣₑₛₑₜ (at Jᵣₑₛₑₜ) and Vₛₑₜ (at Jₛₑₜ). Establishing |Vₛₑₜ|>|Vᵣₑₛₑₜ| enables a switch between conductive and insulative states. Vᵣₑₛₑₜ may be approximately at a band splitting potential arising from correlation and Vset may be approximately twice the band splitting potential.

In particular implementations, the size of the write window 109 110 may be determined, at least in part, by materials and doping of the element. The transition from high resistance (or high capacitance) to low resistance (or low capacitance) can be represented by a singular impedance of the device.

FIG. 1 C shows a schematic diagram of a circuit of a variable impeder device 111. The variable impeder device comprises characteristics of both variable resistance and variable capacitance, for example, a variable resistor 112 in parallel with a variable capacitor 113.

Although the resistor 112 and the capacitor 113 are shown as discrete components such a device may equally be comprised by a CES element which has the characteristics of variable capacitance and variable resistance.

FIG. 1 D shows an example truth table for a variable impeder device 111 such as that shown in FIG. 1C in a conductive memory state and an insulator memory state.

The transition metals, transition metal compounds or transition metal oxides forming the correlated electron material of the switching region (102 FIG. 1a) and the relatively conducting regions (103 FIG. 1a) may be doped with extrinsic ligands. In the case of transition metal oxides, the doping may be generally indicated as MO(Lₓ) wherein the number of ligands (the value of x) is determined by the balance in valences with the elements making up the metal oxide.

The ligand may, for example, comprise a carbon containing ligand. In that case, the doping may be generally indicated as MO(Cₓ) notwithstanding that C can refer to radicals, such a —CO, -Cp or —CH₃, comprising one or more carbon atoms and one or more other atoms.

The ligand may alternatively, comprise a nitrogen, sulphur or phosphorus containing ligand. In that case, the doping may be similarly indicated, for example, as MO(Nₓ) notwithstanding that N can refer to radicals, such a —NH₃, —NC, comprising one or more other atoms.

The amount of ligand (or “dopant”) in the correlated electron material is critical to its behaviour as a switch and sets the resistance value for the switching region in a given applied electric field.

The present disclosure provides a method for forming a thin film comprising a metal, metal compound, or metal oxide with precise control over the incorporation of a dopant.

The method enables precise control over the amount of the dopant not just in a thin film layer but also in the thickness direction of a thin film.

The method further enables the formation of a storage element in a thin film with a controlled thickness for the element.

Accordingly, in a first aspect, the present disclosure provides a method for forming a thin film comprising a metal, metal compound such as metal oxide or metal nitride on a substrate, which method comprises forming one or more thin film layers of a metal, metal compound or metal oxide by a deposition process employing reactant precursors and/or relative amounts thereof which are selected to deposit a thin film layer with a controlled amount of dopant derived from at least one reactant precursor.

The deposition may comprise chemical vapour deposition (CVD), atomic layer deposition (ALD) or physical vapor (PVD). CVD, ALD or PVD may be plasma enhanced or involve remote plasma, laser assisted deposition, or hot wire to increase reactivity of precursors. CVD is a method CVD is a deposition method in which the reactant precursors react in the vapour and on the surface of a substrate. ALD is a deposition method in which the reactant precursors are exposed to the surface one at a time and the reactions are surface and near surface reactions. PVD is a method where a substrate is placed in “line of sight” of a “target” that is sputtered and results in deposition of the sputtered material on the substrate. Line of sight is determined as the path where the stream of precursor formed by the sputtering (by evaporation or bombardment of a target with ions, such as Ar⁺). The ambient in the PVD chamber can be filled with an oxidizer or other source to assist in the proper incorporation of species in the film, and the targets may be comprised of metal, metal oxide, carbon, and or other compounds. Shuttering the PVD target stops the flow of reactants to the substrate. Alternate shuttering of the targets allows control of different sputtered species to the substrate for the PVD process.

Chemical vapor deposition, physical vapor deposition and atomic layer deposition are techniques which are commonly used in the semiconductor industry to form metal, metal compound and metal oxide films which are as pure as possible. That is to say, without the incorporation of an undesired dopant derived from a reactant precursor.

In an atomic layer deposition, the reactant precursors react with the surface of a substrate in a sequential, self-limiting manner

The ALD process typically provides sequential, non-overlapping pulses of the reactant precursors to the surface during a time period allowing for complete reaction of a precursor with the reactive sites. The exposure of the substrate to each precursor constitutes ALD cycle. An overlapping purge cycle from an inert gas may be used to ensure that reactant precursors are not simultaneously present over the substrate.

The time period for each pulse of reactant precursor may vary having regard to the reaction surface of the substrate, the reactants and process conditions such as temperature and pulse flow rate.

A thin film is grown on the surface by repeating ALD and purge cycles over the surface until a desired thickness for the thin film is reached.

An atomic layer deposition may provide a thin film comprising a metal oxide from a metal-containing reactant precursor and an “oxidising” reactant precursor. It may alternatively provide a thin film comprising a transition metal from a metal-containing reactant precursor and a “reducing” reactant precursor.

In one example, an alumina film is formed from trimethylaluminum (TMA) and water. In this example, the formation of the alumina film is thought to occur by dissociative chemisorption of trimethylaluminum during exposure of the surface to trimethylaluminum followed by hydrolysis of the resultant surface methylaluminum species during exposure to water.

The overall reaction, which may be expressed as 2(CH₃)₃Al+3H₂0→Al₂O₃+6CH₄, is generally referred to as an oxidation of trimethylaluminum in which water is the oxidant. Of course, other metal oxide films can be obtained from other organometallic compounds and other oxidants such as ozone, oxygen, nitric oxide, nitrous oxide, and hydrogen peroxide may also be used as well as any of the above with a plasma to provide activated species

In a chemical vapor deposition the reactant precursors are simultaneously exposed to the surface of a substrate. The reactant precursors may react in the vapour phase as well as on the surface but still deposit a thin film of similar composition to atomic layer deposition. An alumina thin film can, for example, be readily formed on the surface of a substrate using the same reactant precursors as for atomic layer deposition.

US 2008/0206539 A1 discloses a method for forming a low friction alumina film for protecting MEMS device surfaces. The method comprises depositing the film by atomic layer deposition at low temperature (≦150° C.) using trimethylaluminum so that it produces a metal oxide containing carbon derived from the trimethylaluminum precursor.

The present disclosure, however, provides a method in which reactant precursors and/or relative amounts of reactant precursors are selected so that control of the amount of a ligand in the film, attached to the metal ion of the transition metal, transition metal oxide, or transition metal compound is controlled through the thickness of the film. The dopant ligand may not be the same species as the initial ligand on the starting precursor for deposition.

The selection of reactant precursors and/or relative amounts of reactant precursors will be made having regard not just to the predetermined time period but also to the temperature, pressure, and surface conditions of the surface being deposited upon as the film grows.

With appropriate values therefore, the selection may provide that one reactant precursor has a low reactivity for another reactant precursor and/or for a reactive site on the surface of the substrate. The selection may alternatively or additionally provide that an amount of one reactant precursor is less than that necessary for complete reaction with another reactant precursor and/or for the reactive sites on the surface of the substrate.

In one implementation, in which the deposition is an atomic layer deposition, the selection provides an oxidising or reducing reactant precursor of reactivity and/or in a relative amount that allows control of the amount of a dopant ligand in the film, attached to the metal ion of the transition metal, transition metal oxide, or transition metal compound is controlled through the thickness of the film. The dopant ligand may not be the same species as the initial ligand on the starting precursor for deposition.

Note, however, that in an atomic layer deposition, the metal-containing precursor may not directly provide reactive sites for an oxidising reactant precursor on the surface of the substrate but that such sites may be produced by reaction of another reactant precursor. The metal-containing reactant precursor may, for example, be a metal halide and the other reactant precursor a hydrocarbon such as ethylene or acetylene. The doping of the transition metal oxide, transition metal or transition metal compound is formed by introducing hydrocarbon following exposure of the substrate to the metal-containing reactant precursor or following exposure of the substrate to an oxidizer or reducing precursor.

The method may control the relative amounts of reactant precursors by controlling the mass flow of at least one reactant precursor, for example, the oxidising reactant precursor to the substrate during the pulsing. The mass flow can be controlled by a mass flow controller (MFC) in a precise and highly repeatable way not least because the reaction boundary layer over the substrate can be controlled by other parameters such as pressure and the direction and speed of gas flow relative to the substrate in a precise and highly repeatable way.

The method may comprise forming a first thin film layer with a controlled amount of dopant and forming a second thin film layer with a controlled amount of dopant, whereby the controlled amount of dopant of the second thin film layer is different to that of the first thin film layer.

The method may further comprise forming a third thin film layer with a controlled amount of dopant, whereby the controlled amount of dopant of the third thin film layer is different to that of the second thin film layer.

The forming of the second thin film layer may, in particular, employ reactant precursors which are selected so that at least one reactant precursor is different to the reactant precursors for the forming of the first thin film layer.

In particular, the metal-containing reactant precursor may be the same for both thin film layers and the oxidising reactant precursor may be different for the second thin film layer as compared to that for the first thin film layer. The oxidising reactant precursor for the second thin film layer may, for example, have lower reactivity for the metal-containing reactant precursor and/or the reactive sites on the surface of the substrate as compared to the oxidising reactant precursor for the first thin film layer. In that case, the second thin film layer will comprise a higher amount of dopant as compared to the first thin film layer.

The forming of the third film layer may employ reactant precursors which are selected to be different to the reactant precursors for the forming of the second thin film layer.

In particular, the metal-containing reactant precursor may be the same for both thin film layers and the oxidising reactant precursor may be different for the third thin film layer as compared to that for the second thin film layer. The oxidising reactant precursor for the third thin film layer may, for example, have higher reactivity for the metal-containing reactant precursor and/or the reactive sites on the surface of the substrate as compared to the oxidising reactant precursor for the second thin film layer. In that case, the third thin film layer will comprise a lower amount of dopant as compared to the second thin film layer.

The forming of the first thin film layer may alternatively or additionally provide relative amounts of reactant precursors which are selected to be different to those for forming the second thin film layer.

In particular, the amount of the metal-containing reactant precursor may be the same for both thin film layers and the amount of oxidising reactant precursor may be different for the second thin film layer as compared to that for the first thin film layer. The amount of the oxidising reactant precursor for the second thin film layer may, for example, be less than that for the first thin film layer. In the case where the oxidising reactant precursor is the same for both thin film layers, the second thin film layer will comprise a higher amount of dopant as compared to the first thin film layer.

The forming of the third thin film layer may also employ process conditions providing relative amounts of reactant precursors which are selected to be different to the process conditions for forming the second thin film layer.

In particular, the amount of the metal-containing reactant precursor may be the same for both thin film layers and the amount of oxidising reactant precursor may be different for the third thin film layer as compared to that for the second thin film layer. The amount of the oxidising reactant precursor for the third thin film layer may, for example, be greater than that for the second thin film layer. In the case where the metal-containing reactant precursor is the same for both thin film layers, and the amount of oxidising precursor is more for the third layer, the third thin film layer will comprise a different if not lower amount of dopant as compared to the second thin film layer.

The method may comprise forming each of the thin film layers at the same deposition temperature notwithstanding that the deposition temperature is one process parameter which affects the incorporation of dopant in a thin film layer. A single deposition temperature for the deposition of the thin film layers avoids time consuming and expensive cycles of cooling and heating. Of course, the selected temperature will take into consideration the reactivity and mass flow of each of the reactant precursors at that temperature.

The metal-containing reactant precursor may comprise any metal compound providing a suitable vapour pressure at the appropriate temperatures or that may be delivered to the surface by a method which is known to the art. It may, in particular, comprise any organometallic compound or metal halide which is known to the art.

Preferably, however, the metal-containing reactant precursor comprises a compound capable of providing a correlated electron material by vapour deposition. The metal-containing reactant precursor may, in particular, comprise a compound of a metal having partially filled d or f electron orbitals. Suitable compounds include those of aluminium and transition or lanthanide metals such as cadmium, chromium, cobalt, copper, gold, iron, manganese, mercury, molybdenum, nickel, palladium, rhenium, silver, tin, titanium, vanadium, yttrium and zinc.

The metal-containing reactant precursor may comprise a compound having one or more ligands for the metal which are capable of providing one or more of carbon, nitrogen, sulphur, phosphorus or halogen doping of a thin film layer. Suitable compounds include metal halides and organometallics containing one or more of a ligand providing electron donation (“back donation”) to the metal and especially those in which the ligand is one or more of chloro, bromo, iodo and organometallic compounds carbonyl, cyano, methyl, carbanato cyclopentadienyl, amino, alkylamino, arylamino, pyridine, bipyridine or acetylacetonate ligands. The one or more ligand may, in particular, be selected from the group consisting of fluoro, chloro, bromo, iodo, carbonyl, cyano, methyl, carbanato, cyclopentadienyl, amino, alkylamino, arylamino, dialkylamino (for example, ethylenediamino), diarylamino, pyridine, bipyridine, 1,10-phenanthrolino, cyanosulfanido (for example, thiocyanato, nitroso, nitrito, nitrato, trialkylphosphino, triarylphosphino (for example, triphenylphosphino), acetonitrilo and acetylacetonato ligands.

The metal-containing reactant precursor may, for example, comprise an organonickel compound or a nickel halide. Suitable such compounds include nickel tetrachloride NiCl₄, nickel carbonyl Ni(Co)₄, nickel amidinate Ni(AMD), dicylcopentadienylnickel Ni(Cp)₂, diethylcyclopentadienylnickel Ni(EtCp)₂, bis(pentamethylcyclopenta-dienyl)nickel Ni(C₅(CH₃)₅)₂, bis(methylcyclopentadienyl)nickel Ni(CH₃C₅H₄)₂, nickel acetylacetonate Ni(acac)₂, bis(2,2,6,6-tetramethylheptane-3,5-dionato)nickel Ni(thd)₂, nickel dimethyl-glyoximate Ni(dmg)₂, nickel 2-amino-pent-2-en-4-onato Ni(apo)₂, bis(1-dimethylamino-2-methyl-2-butanolate)nickel Ni(dmamb)₂ and bis(1-dimethylamino-2-methyl-2-propanolate)nickel Ni(dmamp)₂ and mixtures thereof. Organometallic compounds of other transition or lanthanide metals will be apparent from this list.

Suitable hydrocarbons providing for carbon doping include methane, acetylene, ethane, propane, ethylene and butane and mixtures thereof.

The oxidising reactant precursor may comprise any suitable oxidant. Suitable oxidants include oxygen O₂, ozone O₃, oxygen plasma species, water H₂O, heavy water D₂O, hydrogen peroxide H₂O₂, nitric oxide NO, nitrous oxide N₂O, carbon monoxide CO and carbon dioxide CO₂ and mixtures thereof.

The process conditions for atomic layer deposition may employ a temperature between 20° C. and 1000° C., in particular, between 20° C. and 500° C. and, for example, between 20° C. and 400° C.; a pressure up to 800 Torr, in particular, between 100 mTorr and 760 Torr; an exposure time for the metal-containing reactant precursor of 1 millisecond to 10 minutes, in particular, 0.1 second to 5 minutes; an exposure time for the oxidising reactant precursor of 1 millisecond to 10 minutes, in particular, 0.1 second to 5 minutes; and a purge time between 1 millisecond and 10 minutes, in particular, between 0.1 second and 5 minutes.

The process conditions for chemical vapor deposition may employ a temperature selected from the range of 20° C. to 1000° C., in particular, 20° C. to 500° C.; a pressure up to 800 Torr, in particular between 100 mTorr and 760 Torr; and a deposition time between 3 minutes and 300 minutes.

The method may provide an annealing step after the deposition of the thin film. The post deposition annealing step may employ a temperature selected from between 50° C. and 900° C., a pressure up to 800 Torr, in particular between 0.5 Torr and 760 Torr. Suitable annealing gases include nitrogen, hydrogen, oxygen, ozone, nitric oxide, nitrous oxide, water, carbon monoxide and carbon dioxide. The selection of one or other of these gases may depend on the selection of the oxidising reactant precursor last used.

Note that the method provides for control over the thickness of the thin film by selection in the number of ALD and purge cycles for the atomic layer deposition or by selection in the exposure time for the chemical vapour deposition.

The method may provide that the overall thickness of the thin film (after the annealing step) is between 1 nm and 100 nm, in particular, between 1 nm and 75 nm. The thickness of first and second or first, second and third thin film layers may vary within this overall thickness. The thickness of the second thin film layer may, for example be significantly lower than the thickness of the first thin film layer and the thickness of the third film layer. It may, in particular, have a thickness between 1 nm and 50 nm, for example between land 30 nm.

The method may employ a conventional apparatus which is adapted to include a mass flow controller for at least one reactant precursor and to provide sources for multiple reactant precursors. These sources may, in particular, provide for a single metal-containing reactant precursor and two or more oxidising reactant precursors of widely differing reactivity for the metal-containing reactant precursor and/or the reactive sites of the surface of the substrate.

The mass flow controller may, in particular, be connected to the sources for the reactant precursors other than the metal-containing reactant precursor.

In a second aspect, the present disclosure provides a method for the manufacture of a storage element, which method comprises forming a thin film of a correlated electron material on a substrate by a deposition process depositing a first thin film layer comprising a first amount of dopant, a second thin film layer comprising a second amount of dopant and a third thin film layer comprising a third amount of dopant, whereby the second amount of dopant is different to the first amount of dopant and the third amount of dopant.

Note that the forming of the thin film comprises a continuous deposition process so that the thin film is formed as a single construct.

Note also that each thin film layer may comprise the same dopant derived from at least one reactant precursor used for each thin film layer. However, each thin film layer may comprise a different dopant derived from at least one reactant precursor which is different for each layer. Note further that the first amount of dopant may be the same or different to the third amount of dopant.

The deposition may comprise atomic layer deposition (ALD), chemical vapour deposition (CVD) or physical vapor deposition (PVD). The chemical vapour deposition may comprise a process in which reactant precursors react in the vapour and on the surface of a substrate. The deposition may be plasma, laser or hotwire assisted.

The forming of the thin film may employ any metal-containing reactant precursor which has suitable vapour pressure and is capable of providing an electron correlated material by deposition with another reactant precursor, such as an oxidising or reducing reactant precursor.

The amount of dopant in each thin film layer may be controlled by selection in the reactant precursors and/or deposition process conditions for each thin film layer.

The process conditions which control the amount of dopant in a thin film layer include the temperature of the substrate, the time of the exposures of the substrate as well as the pressure, the selection of reactant species, and the mass flow of the reactant precursors during the exposures.

The process conditions may be selected so that the amount of dopant in each thin film layer is controlled simply by selection in reactant precursors and/or relative amounts of the reactant precursors.

In that case, the depositing of each thin film layer employs the same temperature, pressure and time of exposure. Of course, these parameters will be chosen having regard to the surface area of the substrate and the reactivity of the reactant precursors with each other and/or reactive sites on the surface of the substrate.

With appropriate values therefor, the selection may provide that at least one reactant precursor for the second thin film layer is different to those for the first and third thin film layers.

In one implementation, the selection provides an oxidising or reducing reactant precursor for at least one thin film layer which is different to that for any other thin film layer. This reactant precursor may have a lower or higher reactivity for the metal-containing reactant precursor and/or the reactive sites on the surface of the substrate as compared to that of any other thin film layer.

In particular, the metal-containing reactant precursor may be the same for the first and third thin film layers and the oxidising reactant precursor may be different for the second thin film layer as compared to that for the first and third thin film layers. The oxidising reactant precursor for the second thin film layer may, for example, have lower reactivity for the metal-containing reactant precursor and/or the reactive sites on the surface of the substrate as compared to the oxidising reactant precursor for the first and third thin film layers. In that case, the second thin film layer will comprise a higher amount of dopant as compared to the first and third thin film layers.

The selection may alternatively or additionally provide that an amount of at least one reactant precursor for the second thin film layer is different to the amounts (which may be the same) for the first and third thin film layers.

In particular, the amount of the metal-containing reactant precursor may be the same for the first and third thin film layers and the amount of oxidising reactant precursor may be different for the second thin film layer as compared to that for the first and third thin film layers. The amount of the oxidising reactant precursor for the second thin film layer may, in particular, be less than the amount for the first and third thin film layers.

At least for the case where the metal-containing reactant precursor is the same for both thin film layers, the second thin film layer will comprise a different if not higher amount of dopant as compared to the first and third thin film layers if the oxidising reactant precursor amount is different for the second thin film as compared to the first and third.

The amount of a reactant precursor for a thin film layer may be controlled by a mass flow controller. Thus, the depositing of the second thin film layer may simply comprise providing a different mass flow for one reactant precursor, in particular, the oxidising reactant precursor, to the surface of the substrate as compared to the same or corresponding reactant precursor for forming the first and third thin film layers.

The mass flow controller enables a selection of a reactant precursors and/or amounts of the reactant precursor providing that the amount of dopant in each thin film layer is a controlled amount of dopant.

Note that the amount of dopant in a thin film may be determined, for example, by secondary ion mass spectroscopy (SIMS), Auger electron spectroscopy (AES), X-ray photoelectron spectroscopy and resistance measurements. These determinations can be made, for example, on a single thin film layer and related back to the mass flow controller so that a thin film having one or more thin film layers with a controlled amount of dopant can be obtained.

The method may provide, therefore, a storage element which is tuned by relative amounts of dopant across the thin film layers to an optimum performance, for example, as a memory storage element.

The first, second and third amounts of dopant may provide that the first and third thin film layers are relatively more conductive under normal operation of the element and the second thin film thin film layer is capable of switching from a conductor state to an insulator state (and vice-a-versa) under the normal operating operation of the element. That is to say, the first and third thin film layers provide conductive regions (C) in the element and the second thin film layer provides switching region (S) in the element.

The dopant may, in particular, be a p-type dopant (for example, carbonyl) providing that the thin film is hole conducting. In that case, the first, second and third amounts of dopant may provide a doping profile for the conductive regions and the switching region which may be described as p+/p/p+ or p/p+/p where p indicates that the doping provides for hole conducting in a conductive or switching region and + indicates the relative amount of doping in those regions. The correlated electron material may comprise a metal or a metal compound (such as a metal oxide or nitride) of a metal having partially complete d and f electron orbitals. The metal oxide may, in particular, be selected from the group consisting of Al₂O₃ and transition metal and lanthanide oxides such as NiO, ZnO, Cr₂O₃, Fe₂O₃, YO, TiO₂, MoO₃, V₂O₅, WO₃, CuO, MnO₂, YTiO, CuAlO₂, as well as perovskites including CrSrTiO₃, CrLaTiO₃, and manganates such as PrCaMnO₃ and PrLaMnO₃.

The first, second and third amounts of dopant may, in particular, provide that the resistance in the switching region of the element exhibits a ratio of a low resistance state to a high resistance state of at least 5.0:1.0 in response to a voltage of between 0.1 V and 10.0 V to be applied across a thickness dimension of the film.

The metal-containing reactant precursor may comprise one or more ligands for the metal which are capable of providing one or more of carbon, nitrogen, sulphur, phosphorus or halogen doping of a thin film layer. Suitable ligands include —CO, —SR, —NH₃, —NO, NO₂, —NO₃, —I, —Br, —Cl, —CN, —NCS and —PPh₃.

The metal-containing reactant precursor may comprise a compound having one or more ligands for the metal which are capable of providing one or more of carbon, nitrogen, sulphur, phosphorus or halogen doping of a thin film layer. Suitable compounds include metal halides and organometallics containing one or more of a ligand providing electron donation (“back donation”) to the metal and especially those in which the ligand is one or more of chloro, bromo, iodo and organometallic compounds carbonyl, cyano, methyl, carbanato cyclopentadienyl, amino, alkylamino, arylamino, pyridine, bipyridine or acetylacetonate ligands. The dopant may, in particular, comprise carbon derived from a ligand selected from the group of ligands consisting of carbon containing molecules of the form CₐH_{b}N_{d}O_{f} wherein a≧1 and b, d and f>0, such as carbonyl, cyano, ethylenediamine, 1,10-phenanthroline, bipyridine, pyridine, acetonitrile and cyanosulfanides such as thiocyanate. The dopant may otherwise comprise nitrogen derived from a ligand selected from the group of ligands consisting of nitrogen containing molecules such as nitric oxide, nitrogen dioxide. The dopant may comprise halogen such as fluorine, iodine, bromine and chlorine or sulfur derived from a ligand selected from the group of sulphur containing molecules, such as thioalkyl or thoiaryl.

The metal-containing reactant precursor may, for example, comprise an organonickel compound or a nickel halide. Suitable such compounds include nickel tetrachloride NiCl₄, nickel carbonyl Ni(Co)₄, nickel amidinate Ni(AMD), dicylcopentadienylnickel Ni(Cp)₂, diethylcyclopentadienylnickel Ni(EtCp)₂, bis(pentamethylcyclopenta-dienyl)nickel Ni(C₅(CH₃)₅)₂, bis(methylcyclopentadienyl)nickel Ni(CH₃C₅H₄)₂, nickel acetylacetonate Ni(acac)₂, bis(2,2,6,6-tetramethylheptane-3,5-dionato)nickel Ni(thd)₂, nickel dimethyl-glyoximate Ni(dmg)₂, nickel 2-amino-pent-2-en-4-onato Ni(apo)₂, bis(1-dimethylamino-2-methyl-2-butanolate)nickel Ni(dmamb)₂ and bis(1-dimethylamino-2-methyl-2-propanolate)nickel Ni(dmamp)₂ and mixtures thereof. Organometallic compounds of other transition or lanthanide metals will be apparent from this list.

The oxidising reactant precursor may comprise any suitable oxidant. Suitable oxidants include oxygen O₂, ozone O₃, oxygen plasma species, water H₂O, heavy water D₂O, hydrogen peroxide H₂O₂, nitric oxide NO, nitrous oxide N₂O, carbon monoxide CO and carbon dioxide CO₂ and combinations thereof.

The process conditions for atomic layer deposition may employ a temperature selected from the range between 20° C. and 1000° C., in particular, between 20° C. and 500° C., for example, between 20° C. and 400° C.; a pressure up to 800 Torr, in particular, between 100 mTorr and 760 Torr; an exposure time for the metal-containing reactant precursor of 1 millisecond to 10 minutes, in particular, 0.1 second to 5 minutes; an exposure time for the reactant precursor other than the metal-containing reactant precursor of 1 millisecond to 10 minutes, in particular, 0.1 second to 5 minutes; and a purge time between 1 millisecond and 10 minutes, in particular, between 0.1 second and 5 minutes.

The process conditions for chemical vapour deposition may employ a temperature selected from the range of 20° C. to 1000° C., in particular, between 20° C. to 500° C.; a pressure up to 800 Torr, in particular between 100 mTorr and 760 Torr; and a deposition time between 5 minutes and 300 minutes.

The method may further comprise an annealing step following the deposition of the thin film. The post deposition annealing step may employ a temperature selected from between 50° C. and 900° C., a pressure up to 800 Torr, in particular between 0.5 Torr and 750 Torr. Suitable annealing gases include nitrogen, hydrogen, oxygen, ozone, nitric oxide, nitrous oxide, water, carbon monoxide and carbon dioxide.

The overall thickness of the thin film (after the annealing step) may be between 1 nm and 100 nm, in particular, between 1 nm and 75 nm. The thickness of the individual thin film layers may vary within the overall thickness limit. The thickness of the second layer may, for example be significantly lower than the thickness of the first thin film layer and the thickness of the third film layer. It may, in particular, be between 1 nm and 50 nm, for example between 5 and 30 nm.

The method may further comprise forming an electrode on the substrate prior to forming the thin film of correlated electron material. In that case, the thin film is deposited and the electrode and the method may also comprise forming an electrode on the thin film.

Preferably, however, the electrode materials are matched to the thin film so as to reduce the effects of interface interactions or surface defects which may otherwise affect performance of the element. The match may, in particular, be between electrical properties (for example, conductivity) and/or chemical properties (for example, coefficient of thermal expansion).

In one implementation, the substrate comprises a semiconductor and, in particular, a semiconductor wafer. Note that the method may form the thin film on a part of the substrate or a plurality of thin film layers in different areas of a substrate (using, for example, a mask) and that references to the surface of the area of the substrate should be interpreted accordingly.

The method may employ apparatus which is adapted to include a mass flow controller and sources for multiple reactant precursors. These sources may, in particular, provide for a single metal-containing reactant precursor and two reactant precursors other than the metal-containing reactant precursor, for example, two oxidants of widely differing reactivity for the metal-containing reactant precursor and the reactive sites of the surface of the substrate.

The mass flow controller may, in particular, be connected to the sources for the reactant precursors other than the metal-containing reactant precursor.

In a third aspect, the present disclosure provides a storage device comprising a thin film of a correlated electron material wherein the thin film comprises a first thin film layer comprising a first amount of dopant, a second thin film layer comprising a second amount of dopant and a third thin film layer comprising a third amount of dopant, wherein the second amount of dopant is different to the first amount of dopant and the third amount of dopant.

The first, second and third amounts of dopant may provide that the first and third thin film layers are relatively conductive under normal operation of the element and the second thin film thin film layer is capable of switching from a conductor state to an insulator state (and vice-a-versa) under the normal operating operation of the element. That is to say, the first and third thin film layers provide conductive regions (C) in the element and the second thin film layer provides switching region (S) in the element.

The storage element may comprise one that has been tuned by selection of relative amounts of dopant across the thin film layers to an optimum performance, for example, as a memory storage element.

For example, in the case that the dopant is a p-type dopant (for example, carbonyl) providing that the thin film is hole conducting, the first, second and third amounts of dopant may provide a doping profile for the conductive regions and the switching region which may be described as p+/p/p+ or p/p+/p where p indicates that the doping provides for hole conducting in a conductive or switching region and + indicates the relative amount of doping in those regions.

The first, second and third amounts of dopant may, in particular, provide that the resistance in the switching region of the element exhibits a ratio of a first resistance state to a second resistance state of at least 5.0:1.0 in response to a voltage of between of 0.1 V and 10.0 V to be applied across a thickness dimension of the film.

The correlated electron material may comprise a metal oxide of a metal having partially complete d and f electron orbitals. The metal oxide may, in particular, be selected from the group consisting of Al₂O₃ and transition metal and lanthanide oxides such as NiO, ZnO, Cr₂O₃, Fe₂O₃, YO, TiO₂, MoO₃, V₂O₅, WO₃, CuO, MnO₂, YTiO, CuAlO₂, as well as perovskites including CrSrTiO₃, CrLaTiO₃, and manganates such as PrCaMnO₃ and PrLaMnO₃.

The dopant in the first, second and third thin film layers may be carbon, nitrogen, or halogen and, in particular, comprise one or more metal ligands selected from the group consisting of —CO, —CN, —CH₃, —C₅H₅, —CO₃, —NH₃, —C₅H₅N, —C₁₀H₈N₂ and acac.

The overall thickness of the thin film (after the annealing step) may be between 1 nm and 100 nm, in particular, between 1 nm and 100 nm. The thickness of the individual thin film layers may vary within the overall thickness limit. The thickness of the second layer may, for example, be significantly lower than the thickness of the first thin film layer and the thickness of the third film layer. It may, in particular, be between 1 nm and 50 nm, for example between 5 and 30 nm.

The storage element may further comprise first and second electrodes. The thin film may, for example, be interposed between the electrodes but other electrode configurations are possible. For example, the electrodes may be provided on a single surface of the thin film.

Preferably, the electrode materials are matched to the thin film so as to reduce the effects of border interactions or surface defects which may otherwise affect performance of the element. The match may, in particular, be between electrical properties (for example, conductivity) and/or chemical properties (for example, coefficient of thermal expansion).

In a fourth aspect, the present disclosure provides apparatus for chemical vapour deposition adapted to include a mass flow controller and sources for multiple reactant precursors. These sources may, in particular, provide for a single metal-containing reactant precursor and two or more reactant precursors other than the metal-containing reactant precursor, for example, two or oxidants of differing reactivity for the metal-containing reactant precursor and/or the reactive sites of the surface of the substrate.

The mass flow controller may, in particular, be connected to the sources for the reactant precursors other than the metal-containing reactant precursor.

The presently disclosed methods and storage element will now be described in more detail with reference to the following implementations and the accompanying drawings in which:

FIG. 1 A is a schematic illustration of a storage element comprising a correlated electron material providing a correlated electron switch;

FIG. 1 B is a plot of current density versus voltage for the storage element of FIG. 1 A;

FIG. 1 C is a representation of a circuit element corresponding to the storage element of FIG. 1 A;

FIG. 1 D is a truth table for the storage element of FIG. 1A;

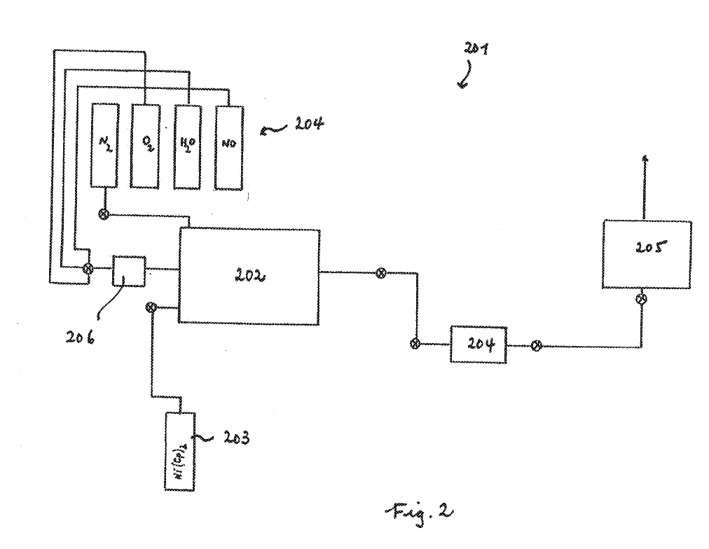

FIG. 2 is a schematic illustration of apparatus for implementing methods for forming the storage element;

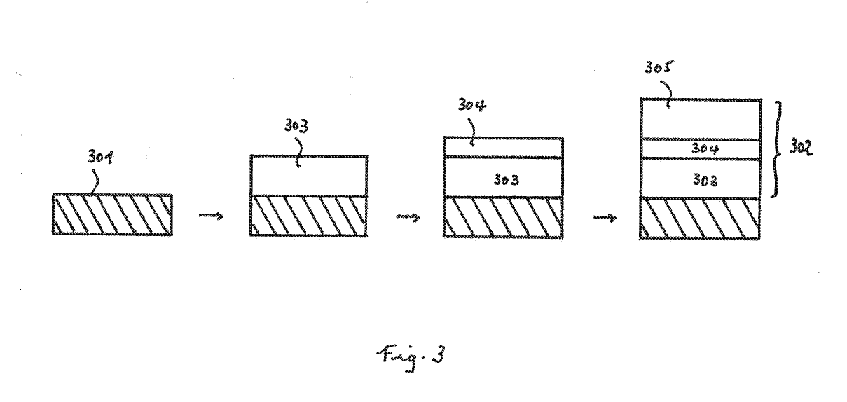

FIG. 3 is a scheme illustrating one method for forming a storage element using the apparatus of FIG. 2; and

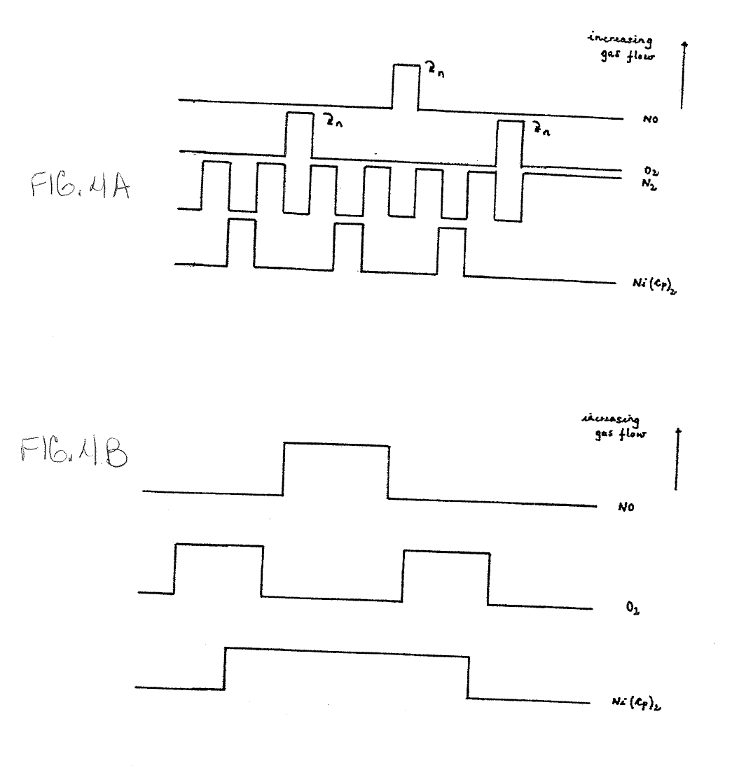

FIG. 4 shows pulse profiles for A atomic layer deposition and B chemical vapour deposition according to the method shown in FIG. 3.

FIG. 2 shows an apparatus 201 for forming a thin film by atomic layer deposition or by chemical vapour deposition. The apparatus comprises a process chamber 202 connected to up line sources of a metal-containing reactant precursor 203 such as dicylcopentadienyl-nickel Ni(Cp)₂, a purge gas N₂ and several reactant precursors 204 comprising oxidants of differing reactivity for the metal-containing reactant precursor, O₂, H₂O and NO. The reactivity of these reactant precursors has the order O₂>H₂0>NO.

The process chamber 202 includes a platform (not shown) providing for the placement of a semiconductor substrate in the middle of the process chamber 202 and equipment (not shown) regulating the pressure, temperature and gas flow within the chamber in combination with a vacuum pump 204 connected to downline of the process chamber 202. The vacuum pump 204 evacuates to an abatement chamber 205 where the reactant precursors and by-products of reaction are made safe before they enter the environment.

The apparatus includes a plurality of independently operable valves which help regulate the gas flow up line and downline of the process chamber. The up line valves allow the reactant precursors and purge gas to enter the process chamber 202 sequentially and enable a selection of one or other oxidant or a particular combination of oxidants for reaction with dicylcopentadienylnickel and/or the surface of the substrate.

The equipment regulating the gas flow in the pressure chamber includes a mass flow controller 206 providing very precise and highly repeatable control of the amount of oxidant introduced into the process chamber in a predetermined time period.

The apparatus is first prepared for use by loading the platform with the semiconductor wafer and evacuating the chamber 202 by operating the vacuum pump 204 and opening the up line valves for the purge gas N₂. During the purging, the process chamber 202 is heated to the temperature which has been selected for the thin film forming process.

Referring also to FIG. 3, a thin film of nickel oxide 302 is then formed on the semiconductor wafer 301 by atomic vapour deposition employing cycles of the following operations. The semiconductor wafer may have prior films and structures already present.

First, the up line valves for the purge gas are closed and the up line valves for the dicylcopentadienylnickel are opened. After a predetermined time period in which the semiconductor wafer is exposed to and reacts with dicylcopentadienylnickel, the up line valves for dicylcopentadienyl-nickel are closed and the up line valves for the purge gas are reopened. After a predetermined time period, the up line valves for the purge gas are closed and the up line valves for NO are opened. After a predetermined time period in which the semiconductor wafer is exposed to and reacts with NO, the up line valves for NO are closed and the up line valves for the purge gas are reopened. The number of cycles of these operations is selected to provide a first thin film layer 303 on the semiconductor wafer of a desired thickness on the semiconductor wafer. The initial order may be the oxidizer first. There may be required a certain number of initial “incubation” cycles, where incubation is known to one skilled in the art as a certain number of exposures of a surface to a precursor that is required to cause initial reactivity.

When the first thin film layer 303 has been formed, a second thin film layer 304 of nickel oxide is formed on the first thin film layer by atomic layer deposition employing cycles of the following operations. First, the up line valves for the purge gas are closed and the up line valves for the dicylcopentadienylnickel are opened. After a predetermined time period in which the first thin film layer is exposed to and reacts with dicylcopentadienylnickel, the up line valves for dicylcopentadienylnickel are closed and the up line valves for the purge gas are reopened. After purging for an appropriate period, the up line valves for the purge gas are closed and the up line valves for oxygen are opened. After a predetermined time period in which the first thin film layer 303 is exposed to and reacts with oxygen, the up line valves for oxygen are closed and the up line valves for the purge gas are reopened. The number of cycles of these operations is selected to provide a second thin film layer 304 of a desired thickness on the first thin film layer 303. The initial order may be the oxidizer first. There may be required a certain number of initial “incubation” cycles, where incubation is known to one skilled in the art as a certain number of exposures of a surface to a precursor that is required to cause initial reactivity.

When the second thin film layer 304 has been formed, a third thin film layer 305 of nickel oxide is formed on the second thin film layer by atomic layer deposition employing cycles of the following operations. First, the up line valves for the purge gas are closed and the up line valves for the dicylcopentadienylnickel are opened. After a predetermined time period in which the second thin film layer 304 is exposed to and reacts with dicylcopentadienylnickel, the up line valves for dicylcopentadienylnickel are closed and the up line valves for the purge gas are reopened. After a predetermined time period, the up line valves for the purge gas are closed and the up line valves for NO are opened. After a predetermined time period in which the second thin film layer 304 is exposed to and reacts with NO, the up line valves for NO are closed and the up line valves for the purge gas are reopened. The number of cycles of these operations is selected to provide a third thin film layer 305 of a desired thickness on the second thin film layer 304. The initial order may be the oxidizer first. There may be required a certain number of initial “incubation” cycles, where incubation is known to one skilled in the art as a certain number of exposures of a surface to a precursor that is required to cause initial reactivity.

The time period during which the semiconductor wafer or thin film layer is exposed to oxygen or NO is selected so that the oxygen gas flow during that period results in the desired amount of dopant ligand bonding to or remaining in the layer.

In that case, the thin film layers will be doped with carbon derived from dicylcopentadienylnickel and the amount of the dopant in the first and third thin film layers 303, 305 will be different than the amount of dopant in the second thin film layer 303.

The gas flows during this time period can be easily adjusted by the mass flow controller so that they are different. The adjustment enables a fine tuning in the relative amount of dopant in the second thin film layer 304 as compared to the dopant in the first and third thin film layers 303, 305.

The gas flow of oxygen or steam during this time period can also be adjusted by dilution with steam. The introduction of a controlled amount of steam in either gas flow enables a fine tuning in the amount of dopant in the second thin film layer 304 as compared to the amount in the first and third thin film layers 303, 305.

The thin film may alternatively be formed on the semiconductor wafer by chemical vapour deposition employing the following operations.

First, the up line valves for the purge gas are closed and the up line valves for the dicylcopentadienylnickel and oxygen are opened. After a predetermined time period in which the semiconductor wafer is exposed to and reacts with the mixture, the up line valves for oxygen are closed. The predetermined time period is chosen so that the first thin film layer 303 forms with the desired thickness under the selected process conditions.

When the first thin film layer 303 has been formed, a second thin film layer 304 may be formed on the first thin film layer 303 by chemical vapour deposition employing the following operations. First, the up line valves for oxygen are opened. The gas flow of oxygen to the chamber 202 is adjusted by the mass flow controller 206 so that it is higher than the gas flow used for the first thin film layer 303. After a predetermined time period in which the first thin film layer 303 is exposed to the mixture, the up line valves for oxygen are closed. The predetermined time period is chosen so that the second thin film layer 304 forms with the desired thickness under the selected process conditions.

When the second thin film layer has been formed, a third thin film layer 305 is formed on the second thin film layer by chemical vapour deposition employing the following operations. First, the up line valves for oxygen are opened. The gas flow of oxygen to the chamber is adjusted by the mass flow controller 206 so that it is the same as the gas flow used for the first thin film layer 303. After a predetermined time period in which the second thin film layer 304 is exposed to and reacts with the mixture, the up line valves for dicylcopentadienylnickel and oxygen are closed and the up line valves for the purge gas are reopened. The predetermined time period is chosen so that the third thin film layer 305 forms with the desired thickness under the selected process conditions.

In either case, when the third thin film layer 305 has been formed, the final nickel oxide thin film 302 is obtained by an annealing carried out in the process chamber 202 during a predetermined time period in which purging with nitrogen is maintained. The temperature of the process chamber 202 and/or the pressure therein may be maintained or adjusted to a selected value or values during this predetermined time period.

FIG. 4 shows the gas flows in the apparatus during the formation of the thin film by A atomic layer deposition and B chemical vapour deposition as described above.

The pulse profile for the chemical vapour deposition shows continuous exposure of the semiconductor wafer to dicylcopenta-dienylnickel and intermittent exposure to a single oxidant wherein the species of oxidant for one exposure is greater than the amount for the other exposures.

The present disclosure provides a method which enables a storage element to be fabricated as a thin film of an electron correlation material by a continuous process. The method also enables the electrical and switching properties of the element to be tuned so that it provides optimum performance through abrupt switching under normal operation conditions.

Note the present disclosure refers in detail to a limited number of implementations and that other implementations which are not described here in detail are possible.

Note also that it is the accompanying claims which particularly point out an invention in the present disclosure and the scope of protection which is sought.

Note further that a reference to a particular range of values in this disclosure (including the claims) includes the starting and finishing values.

1. A method for forming a thin film comprising a metal oxide, which method comprises forming one or more thin film layers of metal oxide by a chemical vapour deposition or an atomic layer deposition process employing reactant precursors comprising a metal-containing reactant precursor and an oxidant to form a first thin film layer with a controlled amount of dopant and a second thin film layer with a controlled amount of dopant wherein the dopant is derived from at least one of the reactant precursors, the oxidant is selected from the group consisting of O₂, O₃, oxygen plasma species, H₂O, D₂O, H₂O₂, NO, N₂O, CO and CO₂ and mixtures thereof and the forming of the first thin film layer employs an oxidant and/or relative amount of an oxidant which is different to the oxidant and/or relative amount of oxidant for forming the second thin film layer whereby the controlled amount of dopant of the second thin film layer is different to that of the first thin film layer.

2. (canceled)

3. A method according to claim 1, which further comprises forming a third thin film layer with a controlled amount of dopant, wherein the forming of the third thin film layer employs an oxidant and/or relative amount of an oxidant which is different to the oxidant and/or relative amount of oxidant for forming the second thin film layer whereby the controlled amount of dopant of the third film layer is different to that of the second thin film layer.

4. A method according to claim 1, wherein the forming of the first thin film layer employs an oxidant which is selected to be different to the oxidant for the forming of the second thin film layer.

5. A method according to claim 3, wherein the forming of the third film layer employs an oxidant which is selected to be different to the oxidant for the forming of the second thin film layer.

6. A method according to claim 1, wherein the forming of the first thin film layer employs a relative amount of oxidant which is selected to be different to the relative amount of oxidant for forming the second thin film layer.

7. A method according to claim 3, wherein the forming of the third thin film layer employs a relative amount of oxidant which is selected to be different to the relative amount of oxidant for forming the second thin film layer.

8. A method according to claim 1, wherein the forming of each thin film layer employs the same deposition temperature.

9. A method according to claim 1, wherein the reactant precursors comprise a metal halide or an organometallic compound selected from the group consisting of NiCl₄, Ni(AMD), Ni(Cp)₂, Ni(thd)₂, Ni(acac)₂, Ni(CH₃C₅H₄)₂, Ni(dmg)₂, Ni(apo)₂, Ni(dmamb)₂, Ni(dmamp)₂, Ni(C₅(CH₃)₅)₂ and Ni(CO)₄.

10. (canceled)

11. A method for the manufacture of a storage element, which method comprises forming a thin film of a correlated electron material on a substrate by a chemical vapour deposition or an atomic layer deposition process depositing a first thin film layer comprising a first amount of dopant, a second thin film layer comprising a second amount of dopant and a third thin film layer comprising a third amount of dopant, from reactant precursors comprising a metal-containing reactant precursor and an oxidant selected from the group consisting of O₂, O₃ oxygen plasma species, H₂O, D₂O, H₂O₂, NO, N₂O, CO and CO₂ and mixtures thereof wherein the depositing of the first thin film layer and the third thin film layer employs an oxidant and/or relative amount of an oxidant which is different to the oxidant and/or relative amount of oxidant for depositing the second thin film layer whereby the second amount of dopant is different to the first amount of dopant and the third amount of dopant.

12. A method according to claim 11, wherein the second amount of dopant is greater than the first amount of dopant and the third amount of dopant.

13. A method according to claim 12, wherein the second amount of dopant is less than the first amount of dopant and the third amount of dopant.

14. A method according to claim 11, wherein the first amount of dopant and the third amount of dopant are the same.

15. A method according to claim 11, wherein the correlated electron material is a metal oxide selected from the group consisting of NiO, ZnO, Al₂O₃, Cr₂O₃, Fe₂O₃, YO, TiO₂, MoO₃, V₂O₅, WO₃, CuO, MnO₂, YTiO and CuAlO₂.

16. A method according to claim 15, wherein the dopant is carbon or nitrogen derived from a ligand selected from the group of ligands consisting of carbon containing molecules of the form CₐH_{b}N_{d}O_{f} (in which a≧1, and b, d and f≧0), nitric oxide (NO), and nitrogen dioxide (NO₂), or Fluorine (F), Iodine (I), Bromine (Br); or sulfur (S) derived from a ligand selected from the group of sulfur containing molecules consisting of thioalkyl or thioaryl.

17. A storage device comprising a thin film of a correlated electron material wherein the thin film comprises a first thin film layer comprising a first amount of dopant, a second thin film layer comprising a second amount of dopant and a third thin film layer comprising a third amount of dopant, wherein the second amount of dopant is different to the first amount of dopant and the third amount of dopant.

18. A storage device element according to claim 17, wherein the second amount of dopant is greater than the first amount of dopant and the third amount of dopant.

19. A storage device according to claim 17, wherein the correlated electron material is a metal oxide selected from the group consisting of NiO, ZnO, Al₂O₃, Cr₂O₃, Fe₂O₃, YO, TiO₂, MoO₃, V₂O₅, WO₃, CuO, MnO₂, YTiO and CuAlO₂.

20. A storage device according to claim 18, wherein the dopant is carbon or nitrogen derived from a ligand selected from the group of ligands consisting of carbon containing molecules of the form CₐH_{b}N_{d}O_{f} (in which a≧1, and b, d and f≧0) such as: carbonyl (CO), cyano (CN⁻), ethylene diamine (C₂H₈N₂), phen(1,10-phenanthroline) (C₁₂H₅N₂), bipyridine (C₁₀,H₈N₂), ethylenediamine ((C₂H₄(NH₂)₂), pyridine (C₅H₅N), acetonitrile (CH₃CN), and cyanosulfanides such as thiocyanate (NCS⁻); in addition nitric oxide (NO), Nitrogen dioxide (NO₂), halides such as Fluorine (F), Iodine (I), Bromine (Br); and sulfur (S) and other ligands such that result in correlated electron behaviour, control or stabilization.

21. A method according to claim 1, wherein the relative amounts of oxidants are controlled by controlling mass flows of oxidants using a mass flow controller.

22. A method according to claim 11, wherein the relative amounts of oxidants are controlled by controlling mass flows of oxidants using a mass flow controller.

23. A method according to claim 11, wherein the relative amounts of oxidants are controlled by controlling mass flows of oxidants using a mass flow controller.

24. A method according to claim 3, wherein the forming of each thin film layer employs the same deposition temperature.
